(19) United States
(12) Patent Application Publication
(10) Pub. No.: US 2025/0120381 A1
(43) Pub. Date: Apr. 17, 2025

(54) FISHING REEL

(71) Applicant: Shimano Inc., Osaka (JP)

(72) Inventors: Kunio TAKECHI, Osaka (JP); Hiroaki GODA, Osaka (JP)

(21) Appl. No.: 18/771,403

(22) Filed: Jul. 12, 2024

(30) Foreign Application Priority Data
Oct. 12, 2023 (JP) 2023-176586

(51) Int. Cl. A01K 89/033; H05K 9/00

(52) U.S. Cl. CPC A01K 89/045; H05K 9/0075

(57) ABSTRACT

A fishing reel includes a reel body, an electronic circuit unit, a communication unit, and a shielding part. The electronic circuit unit is disposed in the reel body. The communication unit communicates with an external electronic device. The shielding part is disposed between the electronic circuit unit and the communication unit and is configured to magnetically shield the electronic circuit unit from the communication unit.

### CROSS-REFERENCE TO RELATED APPLICATIONS

This application claims priority to Japanese Patent Application No. 2023-176586, filed on Oct. 12, 2023.The entire disclosure of Japanese Patent Application No. 2023-176586 are hereby incorporated by reference.

### BACKGROUND

### Technical Field

The present disclosure relates to a fishing reel.

### Background Information

Communication methods that are configured to automatically carry out Near Field wireless Communication (NFC), when one electronic device enters a field in which it is possible to communicate with another electronic device, are known from the prior art (for example, refer to Japanese published unexamined application 2015-76775 Official Notice).

Fishing reels in which braking parameter settings can be changed using an electronic device external to the reel are known (for example, refer to Japanese Patent No. 71,66,895).

### SUMMARY

It has been determined that there is a need to restrict or avoid an increase in the size of a fishing reel such as the reels disclosed in Japanese published unexamined application 2015-76775 Official Notice and Japanese Patent No. 7,166,895, even if a communication unit that can improve communication efficiency, such as an antenna, is provided.

The present disclosure was conceived in light of these circumstances, and an object thereof is to provide a fishing reel in which it is possible to install a communication unit that can improve communication efficiency, such as an antenna, while restricting or avoiding an increase in the size of the reel.

A first aspect of a fishing reel according to the present disclosure comprises: a reel body; an electronic circuit unit provided in the reel body; a communication unit that can communicate with an external electronic device; and a shielding part that is provided between the electronic circuit unit and the communication unit and magnetically shields the electronic circuit unit from the communication unit.

By the first aspect of the fishing reel according to the present disclosure, a shielding part is disposed between the communication unit and the electronic circuit unit. The shielding part can suppress the magnetic effect of magnets, circuit boards, etc., that are received by the communication unit from the electronic circuit unit, thereby establishing good communication with electronic devices. Moreover, the inductor value in the communication unit can be adjusted and the communication range can be increased.

In addition, it is possible to reduce the thickness and size of fishing reels equipped with a communication unit, by simply providing a shielding part.

A second aspect of the present disclosure is the fishing reel according to the first aspect, wherein the shielding part is preferably a magnetic sheet.

In this case, since a thin magnetic sheet can be disposed, the thickness and size of the fishing reel can be further reduced.

A third aspect of the present disclosure is the fishing reel according to the first aspect, wherein the shielding part preferably has a magnetic sheet and/or a copper foil, in accordance with the magnitude of the inductor value.

In this case, for example, if the inductor value is small, a magnetic sheet can be disposed as an adjustment to increase the inductor value. If the inductor value is large, a copper foil can be disposed as an adjustment to reduce the inductor value.

A fourth aspect of the present disclosure is the fishing reel according to any one of the first to the fourth aspects, wherein the electronic circuit unit can have a storage unit that stores setting information, and a control unit that causes the communication unit and the electronic device to communicate when the communication unit and the electronic device enter a field in which Near Field wireless Communication is possible, and that updates the setting information of the storage control unit.

In this case, if an electronic device such as a smartphone is brought close to a portion of a fishing reel in which a communication unit is incorporated, Near Field wireless Communication is automatically performed between the communication unit and the electronic device, the electronic device can receive supply of power, and the communication unit can receive setting information of the electronic device. The setting information received by the communication unit can be communicated with the electronic circuit unit. In this case as well, because a shielding part is disposed between the communication unit and the electronic circuit unit, it is possible to suppress the electrical impact that the electronic circuit unit has on the Near Field wireless Communication, thereby establishing good communication.

A fifth aspect of the present disclosure is the fishing reel according to any one of the first to the fourth aspects, wherein the communication unit can be an antenna substrate on which a pattern coil is disposed, and the shielding part can be disposed on a surface of the antenna substrate facing the electronic circuit unit.

In this case, it is possible to easily form a pattern coil by printing conductive paint, for example, on the substrate. Even when such an antenna substrate is employed, a shielding part can be disposed between the antenna substrate and the electronic circuit unit to adjust the inductor value to be larger.

A sixth aspect of the present disclosure is the fishing reel according to any one of the first to the fifth aspects, wherein the electronic circuit unit can include a braking part that controls the braking force of a spool, and the shielding part can magnetically shield the braking part from the communication unit.

In this case, because the communication unit is shielded from the magnetism of the braking magnet, it is possible to prevent the communication between the communication unit and the electronic device from being affected by magnetism. As a result, it is possible to prevent deterioration in the communication accuracy in the communication unit.

By the fishing reel according to the present disclosure, it is possible to provide a communication unit that can improve communication efficiency, such as an antenna, while restricting or avoiding an increase in the size of the reel.

### BRIEF DESCRIPTION OF THE DRAWINGS

FIG. 1 is a perspective view of a dual-bearing reel according to a first embodiment of the present disclosure.

FIG. 2 is an exploded perspective view o f a dual-bearing reel comprising a brake unit.

FIG. 3 is an exploded perspective view of a brake unit.

FIG. 4 is a partially exploded perspective view of a communication mechanism.

FIG. 5 is a plan view of an antenna substrate of the communication mechanism shown in FIG. 4.

FIG. 6 is a perspective view of a communication mechanism of a dual-bearing reel according to a second embodiment.

FIG. 7 is an exploded perspective view showing a configuration in which a shielding sheet is provided in the communication mechanism shown in FIG. 6.

### DETAILED DESCRIPTION OF EMBODIMENTS

An embodiment of the fishing reel according to the present disclosure will be described below with reference to the drawings. In each of the drawings, there are cases in which the scale of each component has been appropriately changed as required to improve the visibility of the component.

### Embodiment 1

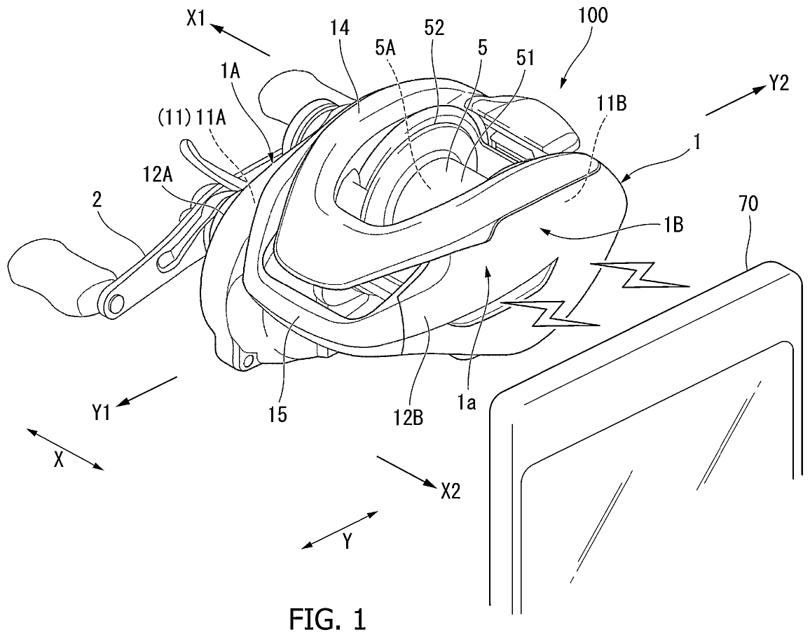

As shown in FIG. 1, a fishing reel of the present embodiment is illustrated as a dual-bearing reel 100.

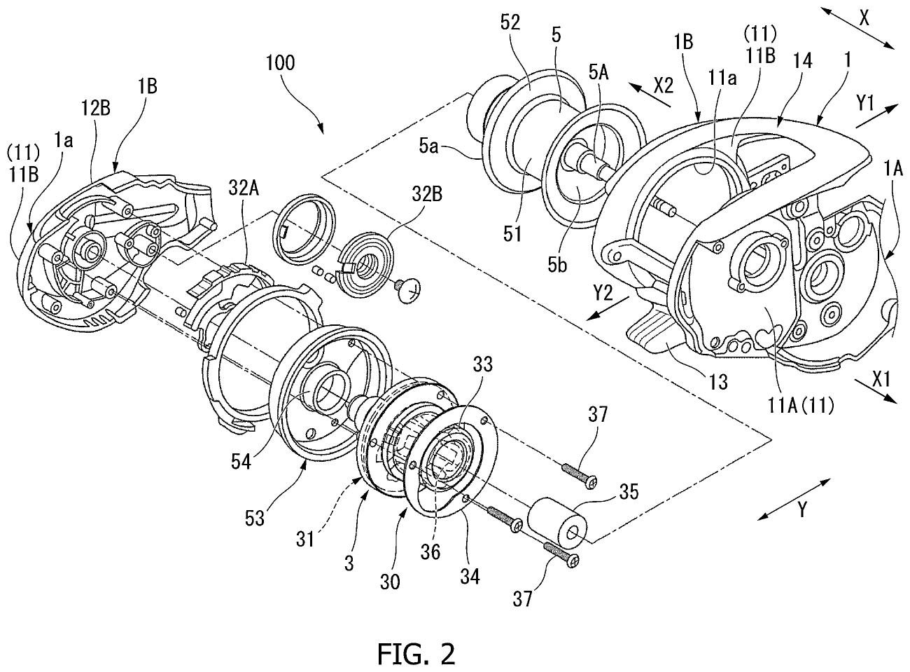

In the following description, “front/back,” “left/right,” and “up/down” refer to the directions shown in FIG. 1. That is, in the front-rear direction Y, the direction in which the fishing line is released is referred to as “front side Y1” and the direction in which the fishing line is wound is referred to as “rear side Y2.” In addition, in the left-right direction X, “right side X1” is a first portion side of the present disclosure and the side on which a handle 2 is disposed in the present embodiment, and “left side X2” is a second portion side of the present disclosure, and is a portion different from the first portion. In FIGS. 1 and 2, the front-rear and left-right directions are reversed.

The same elements are given the same codes in the explanation, and redundant explanations will be omitted.

The dual bearing reel 100 comprises a reel body 1, a handle 2, a spool 5, and a brake unit 3 (refer to FIG. 2) that electrically brakes the spool 5.

As shown in FIG. 1, the dual bearing reel 100 has a reel body 1 provided with left and right side plates 1A, 1B. The left and right side plates 1A, 1B are configured such that left and right frames 11 (11A, 11B) are respectively covered by side covers 12A, 12B. A reel foot 13 (refer to FIG. 2) that is mounted on a fishing rod (not shown) and that is positioned between the left and right side plates 1A, 1B is integrally formed with the reel body 1. In the present embodiment, the handle 2 for rotationally driving the spool 5 is installed on the right side plate 1A side. In addition, in the present embodiment, the outer surface portion of the left side plate 1B is referred to as a palming side portion 1a.

A spool shaft 5A is supported, via a shaft bearing, between the left and right frames 11A, 11B so as to be rotatable. The spool 5, around which a fishing line is wound, is integrally fixed to the spool shaft 5A. In addition, a thumb rest 14, on which a finger can be placed, is disposed between the left and right side plates 1A, 1B above the spool 5.

The frame 11 has a right side plate 1A (i.e., a first portion) disposed on the handle 2 side, a left side plate 1B (i.e., a second portion) disposed on the opposite side of the right side plate 1A in the left-right direction, and a plurality of connecting portions 15 that connect the right side plate 1A and the left side plate 1B. The left side plate 1B has a circular opening 11a through which the spool 5 can pass. A detachable shaft supporting part 53 is disposed on the left side plate 1B of the frame 11.

The thumb rest 14 protrudes outward from the upper portions of the left and right pair of side plates 1A, 1B.

A rotation transmission mechanism (not shown) that transmits the rotation of the handle 2 to the spool 5, a drag mechanism, and a clutch control mechanism are provided between the right side plate 1A and the first side cover 12A.

The handle 2 is supported by the reel body 1 so as to be freely rotatable. The spool 5 is disposed in the reel body 1 between the right side plate 1A and the left side plate 1B so as to be freely rotatable.

The spool 5 has a line winding part 5 around which the fishing line can be wound, and a cylindrical portion 52 that is integrally formed with the line winding part 51 and that is fixed to the spool shaft 5A. The spool shaft 5A is connected to the inner circumferential surface of the cylindrical portion 52 so as to be integrally rotatable therewith. One end 5a of the spool shaft 5A is supported on the shaft supporting part 53, described further below, by a shaft bearing 54 so as to be freely rotatable. The other end 5b of the spool shaft 5A is supported on the first side cover 12A by a shaft bearing (not shown) so as to be freely rotatable.

The shaft supporting part 53 supports one end 5a of the spool shaft 5A of the spool 5 so as to be freely rotatable. A shaft bearing 54 for supporting the one end 5a of the spool shaft 5A so as to be freely rotatable is provided at the center of the shaft supporting part 53.

The brake unit 3 includes a second side cover 12B that includes the shaft supporting part 53. The brake unit 3 comprises a braking part 30, a circuit board 31 (electronic circuit unit), adjustment mechanisms 32A, 32B that adjust the braking force of the braking part 30, a cover member 33, and a magnetic flux shielding member 34.

The braking part 30 includes a braking magnet 35 that is integrally rotatable with the spool 5, and a plurality of coils 36 that are cylindrically arranged at prescribed intervals on the outer peripheral side of the braking magnet 35 and that are connected in series. The coil 36 is one example of a conductor. The braking magnet 35 is mounted on the spool shaft 5A so as to be integrally rotatable therewith. In this embodiment, the braking magnet 35 is fixed to the spool shaft 5A by adhesion. The braking magnet 35 is a cylindrical magnet. The plurality of coils 36 are mounted on the circuit board 31. The two ends of the plurality of coils 36 that are connected in series are electrically connected to the circuit board 31. In this embodiment, four of the coils 36 are provided. Each of the coils 36 is curved in an arc shape, and the plurality of coils 36, as a whole, has a cylindrical shape.

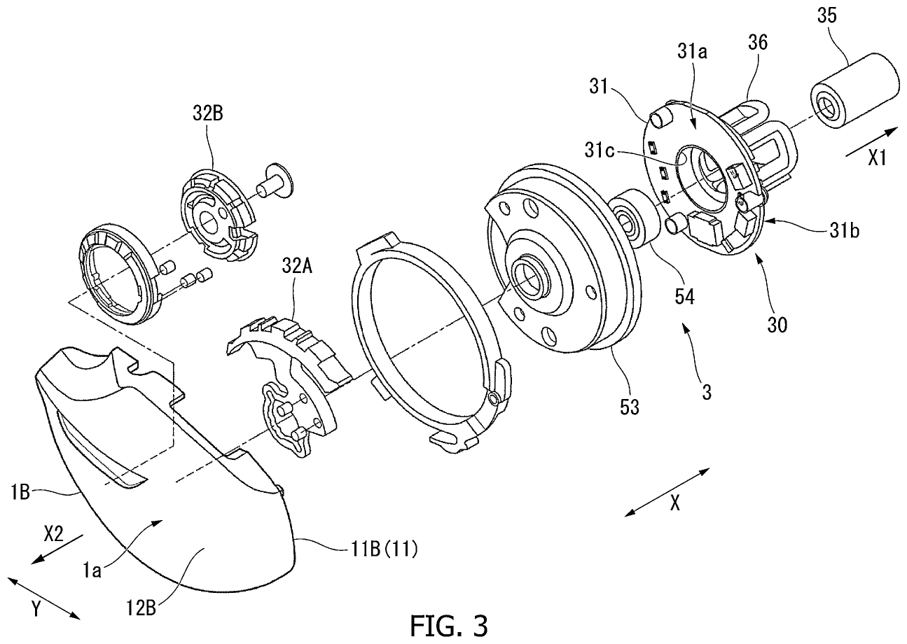

As shown in FIG. 3, the circuit board 31 is formed in a disk shape having a through-hole 31c. The circuit board 31 is mounted on a surface opposing the spool 5 on the outer peripheral side of the shaft supporting part 53. The circuit board 31 has a first surface (front surface 31a) on which the coils 36 are mounted, and a second surface (rear surface 31b) on the opposite side of the front surface 31a. The circuit board 31 is fixed, together with the shaft supporting part 53, the cover member 33, and the magnetic flux shielding member 34, to the left side cover 12B by bolt members 37, shown in FIG. 2.

The cover member 33 is a stepped cylindrical member made of synthetic resin, provided in order to insulate the circuit board 31, the coils 36, and electric components mounted on the circuit board 31.

The magnetic flux shielding member 34 is, for example, a member made of an iron plate. At least a portion of the magnetic flux shielding member 34 is provided on the front surface 31a of the circuit board 31. The magnetic flux shielding member 34 shields the magnetic flux of the braking magnet 35.

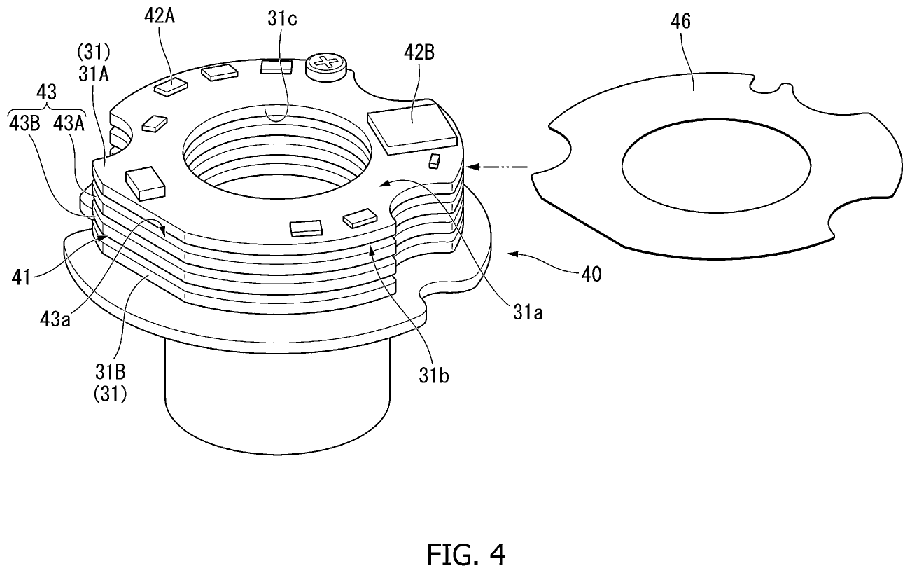

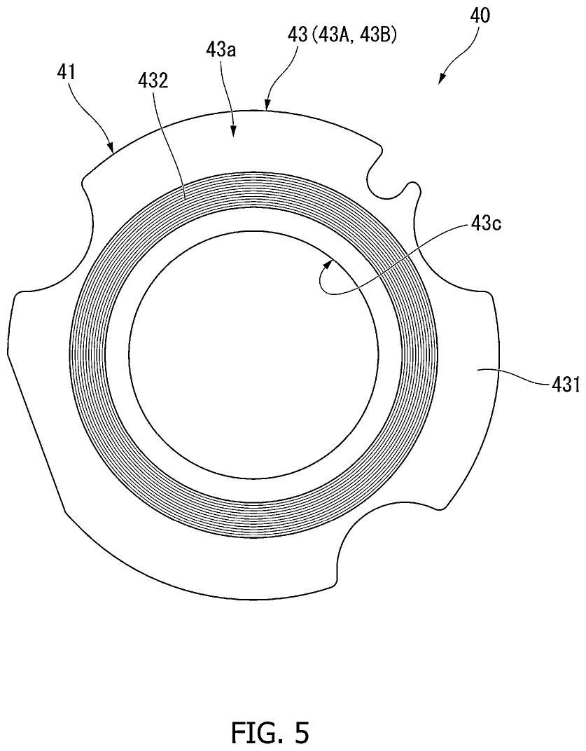

FIG. 4 is a partially exploded perspective view of a communication mechanism 40. FIG. 5 is a plan view of an antenna substrate 43 of the communication mechanism 40 shown in FIG. 4.

As shown in FIGS. 4 and 5, the communication mechanism 40 for communicating information with an external terminal device 70 (electronic device) shown in FIG. 1 is disposed on the second side plate 1B side (palming side portion 1a side) inside the reel body 1. The communication mechanism 40 comprises a storage unit 42A that is disposed in the reel body 1 and stores setting information, an antenna unit 41 (i.e., a communication unit or communicator) that is disposed on the left side plate 1B and that can communicate with the terminal device 70, and a control unit 42B that causes the antenna unit 41 and the terminal device 70 to communicate when the antenna unit 41 and the terminal device 70 enter a field in which Near Field wireless Communication is possible, and updates the setting information of the storage unit 42A.

The communication mechanism 40 employs Near Field wireless Communication, such as NFC (Near Field Communication).

The terminal device 70 is used by a user who is an angler. The terminal device 70 can be, for example, a smartphone, a tablet terminal, or the like.

As shown in FIG. 4, the circuit board 31 described above is composed of a pair of circuit boards 31A, 31B. The antenna unit 41 functions as an antenna for wireless communication, and is stacked sandwiched between the pair of circuit boards 31A, 31B. The antenna unit 41 includes a plurality of layers (two layers here) of the antenna substrate 43 (43A, 43B) on which the pattern coil 432 is formed. The antenna substrate 43 is a multilayer antenna substrate on which a plurality of layers of the pattern coil 432 is formed. That is, the antenna substrate 43 has a substrate body 431 made of resin, or the like, in the form of a thin plate, and a pattern coil 432 printed on one surface (front surface 43a) of the substrate body 431.

The connection between the pattern coils 432 of the plurality of layers of the antenna substrate 43, the connection between the pattern coil 432 and, for example, a tag IC provided on the antenna substrate 43, and the like, can be achieved using the BtoB method or the pin method.

The antenna substrates 43A, 43B are each configured to have an annular shape, and are provided around the spool shaft 5A that is supported by the reel body 1 when viewed from the left-right direction. The substrate body 431 includes a through-hole formed to have essentially the same diameter as the circuit board 31, and is stacked coaxially with the circuit boards 31A, 31B.

The pattern coil 432 is an antenna element that is formed on the front surface 43a of the antenna substrate 43 by printing a conductive material.

In this manner, the antenna substrate 43 is arranged in the vicinity of an inner surface 12a of the left side cover 12B of the left side plate 1B. As a result, by bringing the terminal device 70 close to, or in contact with, the left side plate 1B, as shown in FIG. 1, the terminal device 70 comes within a distance over which information can be communicated with the antenna unit 41, so that information can be communicated therebetween.

In addition, as shown in FIG. 4, the antenna substrates 43A, 43B include or field attached to a shielding sheet 46 (shielding part) that provides magnetic shielding. That is, the shielding sheet 46 is a magnetic sheet. Here, magnetic shielding refers to portions with relatively low magnetic permeability compared to portions that have magnetic permeability. The shielding sheet 46 is arranged between the antenna substrate 43 and the circuit board 31. The shielding sheet 46 is formed in an annular shape having essentially the same shape as the substrate body 431 of the antenna substrate 43 in plan view.

The storage unit 42A and the control unit 40 are mounted on the circuit board 31 of the communication mechanism 40. The storage unit 42A includes, for example, a semiconductor memory, and stores programs and data used for operation, and results of calculations performed by the control unit 42B.

The control unit 42B can include, for example, a transmission unit. In this case, the control unit 42B can output, as transmission data from the transmission unit, to an output unit (not shown) disposed in the reel body 1. For example, the output unit is a unit that presents images, sounds, vibrations, etc., to the user of the dual bearing reel 100, such as a speaker or a display function unit, such as a liquid crystal display, that can be viewed by the angler.

The action of the dual bearing reel 100 configured in this manner will be described in detail next, based on the drawings.

The dual bearing reel 100 according to the present embodiment comprises: the reel body 1; the circuit board 31 disposed in the reel body 1; the antenna unit 41 that can communicate with the external terminal device 70; and the shielding sheet 46 that is disposed between the circuit board 31 and the antenna unit 41 and magnetically shields the circuit board 31 from the antenna unit 41.

In the dual bearing reel 100 according to the present embodiment, the shielding sheet 46 is disposed between the antenna unit 41 and the circuit board 31 to suppress the magnetic effect of magnets, circuit boards, etc., that the antenna unit 41 receives from the circuit board 31, thereby enabling good communication with the terminal device 70. Moreover, the inductor value in the antenna unit 41 can be adjusted and the communication range can be increased.

In addition, by the present embodiment, it is possible to reduce the thickness and size of the dual bearing reel 100 equipped with the antenna unit 41, by simply providing the shielding sheet 46.

Additionally, in the present embodiment, since the shielding sheet 46 is a magnetic sheet, the thickness and size of the dual bearing reel 100 can be further reduced.

In addition, in the present embodiment, the shielding sheet 46 has a magnetic sheet and/or a copper foil of the shielding sheet 46, in accordance with the magnitude of the inductor value.

As a result, for example, if the inductor value is small, a magnetic sheet can be disposed as an adjustment to increase the inductor value. If the inductor value is large, a copper foil can be disposed as an adjustment to reduce the inductor value.

In addition, in the present embodiment, the circuit board 31 comprises the storage unit 42A that stores setting information, and the control unit 42B that causes the antenna unit 41 and the terminal device 70 to communicate when the antenna unit 41 and the terminal device 70 enter a field in which Near Field wireless Communication is possible, and updates the setting information of the storage unit 42A.

As a result, if the terminal device 70 such as a smartphone is brought close to a portion (left side plate 1B) of the dual bearing reel 100 in which the antenna unit 41 is incorporated, Near Field wireless Communication is automatically performed between the antenna unit 41 and the terminal device 70, the electronic device can receive supply of power, and the antenna unit 41 can receive setting information of the terminal device 70. The setting information received by the antenna unit 41 can be communicated with the circuit board 31. In this case as well, because the shielding sheet 46 is disposed between the antenna unit 41 and the circuit board 31, it is possible to suppress the electrical impact that the circuit board 31 has on the Near Field wireless Communication, thereby enabling good communication.

In addition, in the present embodiment, the antenna unit 41 is the antenna substrate 43 on which the pattern coil 432 is formed. The shielding sheet 46 is arranged on a surface of the antenna substrate 43 facing the circuit board 31.

It is thereby possible to easily form the pattern coil 432 by printing conductive paint, for example, on the substrate body 431. Even when such an antenna substrate 43 is employed, the shielding sheet 46 can be disposed between the antenna substrate 43 and the circuit board 31 to adjust the inductor value to be larger.

Additionally, in the present embodiment, the circuit board 31 includes the braking part 30 that controls the braking force of the spool 5. The shielding sheet 46 magnetically shields the braking part 30 from the antenna unit 41.

As a result, because the magnetism of the braking magnet is shielded from the antenna unit 41, it is possible to prevent the communication between the antenna unit 41 and the terminal device 70 from being affected by magnetism. As a result, it is possible to prevent deterioration in the communication accuracy in the antenna unit 41.

By the dual bearing reel 100 according to the present embodiment configured as described above, it is possible to install the antenna unit 41 that can improve communication efficiency while restricting or avoiding an increase in the size of the reel.

Another embodiment of the fishing reel according to the present disclosure will be described next. Compositional elements that have the same functions as the compositional elements of the above-described first embodiment are given the same codes and detailed descriptions thereof are omitted to avoid redundant descriptions.

### Embodiment 2

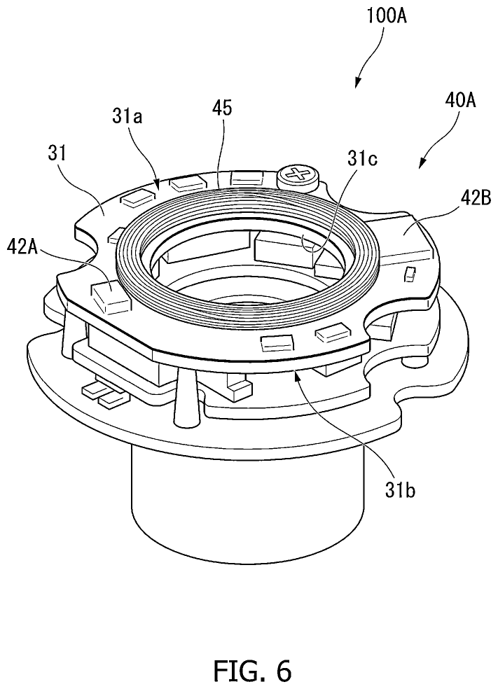

FIG. 6 is a perspective view showing the configuration of a communication mechanism 40A of a dual-bearing reel 100A according to a second embodiment.

As shown in FIG. 6, the communication mechanism 40A according to the second embodiment has a configuration in which an air core coil 45 (communication unit), made of enameled wire wound a plurality of times, is disposed on the front surface 31a of the circuit board 31 on the left side plate 1B side.

The air core coil 45 is wound in an annular shape along the circular through-hole 31c on the front surface 31a of the circuit board 31. The air core coil 45 is disposed so as not to protrude in the radially inward direction of the through-hole 31c of the circuit board 31. The air core coil 45 has an overall cross-sectional diameter of, for example, 1.7-2.0 mm, and the number of turns of the annular winding is set to about 15 turns.

Any appropriate method, such as normal winding or a-winding, can be employed as the method of winding the enameled wire in the air core coil 45.

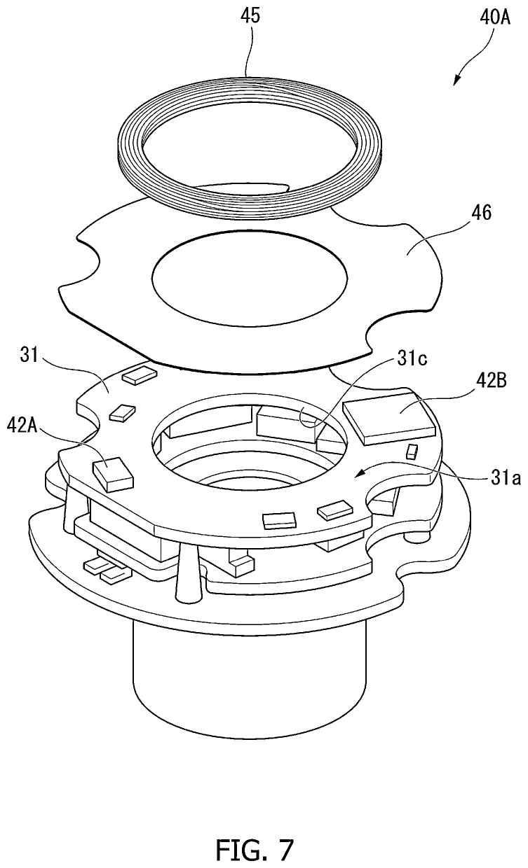

FIG. 7 is an exploded perspective view showing a configuration in which the shielding sheet 46 is disposed in the communication mechanism 40A shown in FIG. 6. In the communication mechanism 40A of the present embodiment, the shielding sheet 46 (shielding part) is disposed between the air core coil 45 and the storage unit 42A, as shown in FIG. 7.

In the second embodiment, since the air core coil 45 is simply disposed on the existing circuit board 31, assembly of the air core coil 45 can be easily carried out. It is a particularly effective structure if there is space in the height direction (left-right direction) above the circuit board 31.

The above-described embodiment of the fishing reel according to the disclosure is presented as an example and is not intended to limit the scope of the disclosure. The embodiments can be implemented in a variety of other forms; furthermore, various omissions, substitutions and changes can be made without departing from the essence of the disclosure. Embodiments include those that can be easily conceived of by a person skilled in the art, those that are substantially the same, and those that are of equivalent scope.

For example, the configuration and the position where a communication unit, such as the antenna unit 41, is disposed in the reel body 1 are not limited to the embodiments described above. For example, the position is not limited to the left side plate 1B on the opposite side of the handle 2, which is provided on the right side plate 1A, as described above. That is, the communication unit can be provided at positions such as an inner layer of the substrate, on one side of the substrate, between the substrate and a case (side plates 1A, 1B of the reel body 1), in the case itself, or on the outer side of the case.

Additionally, in the present embodiment, the shielding sheet 46 made of a magnetic sheet is employed as the shielding part, but no limitation is imposed by such a sheet-like configuration; shielding parts having other shapes can be used. In short, it suffices if the shielding part is provided between an electronic circuit unit and a communication unit and magnetically shields the electronic circuit unit from the communication unit.

In addition, in the present embodiment, the electronic circuit unit (circuit board 31) is configured to comprise the storage unit 42A and the control unit 42B, but no limitation is imposed thereby.

In addition, configurations such as the sizes and shapes of the reel body 1, the spool 5, the handle 2, the brake unit 3, and the like, can be changed as appropriate.

What is claimed is:

1. A fishing reel, comprising
a reel body;
an electronic circuit unit disposed in the reel body;
a communication unit configured to communicate with an external electronic device; and
a shielding part disposed between the electronic circuit unit and the communication unit and configured to magnetically shield the electronic circuit unit from the communication unit.

2. The fishing reel according to claim 1, wherein the shielding part is a shielding sheet.

3. The fishing reel according to claim 1, wherein
the shielding part has at least one of a magnetic sheet or a copper foil, in accordance with a magnitude of an inductor value.

4. The fishing reel according to claim 1, wherein
the electronic circuit unit has
a storage unit configured to store setting information, and
a control unit configured to cause the communication unit and the electronic device to communicate when the communication unit and the electronic device are disposed in a field capable of enabling Near Field wireless Communication, and configured to update the setting information of the storage control unit.

5. The fishing reel according to claim 1, wherein
the communication unit is an antenna substrate on which a pattern coil is disposed, and
the shielding part is disposed on a surface of the antenna substrate facing the electronic circuit unit.

6. The fishing reel according to claim 1, wherein
the electronic circuit unit includes a braking part configured to control the braking force of a spool, and
the shielding part is configured to magnetically shield the braking part from the communication unit.
